(19) United States
(12) Patent Application Publication
(10) Pub. No.: US 2021/0238763 A1
(43) Pub. Date: Aug. 5, 2021

(54) LAMINATED ANODIC OXIDE FILM STRUCTURE

(71) Applicant: POINT ENGINEERING CO., LTD., Asan (KR)

(72) Inventors: Bum Mo AHN, Suwon (KR); Sung Hyun BYUN, Hwaseong (KR); Dong Hyeok SEO, Asan (KR)

(21) Appl. No.: 17/128,770

(22) Filed: Dec. 21, 2020

(30) Foreign Application Priority Data
Jan. 30, 2020 (KR) 10-2020-0010991

(51) Int. Cl. C25D 11/24; C25D 11/12; B32B 15/01; B32B 7/12

(52) U.S. Cl. CPC C25D 11/246; B32B 7/12; B32B 15/017; C25D 11/12

(57) ABSTRACT

Proposed is a laminated anodic oxide film structure in which a plurality of anodic oxide films are stacked. More particularly, proposed is a laminated anodic oxide film structure having a high degree of strength.

### CROSS REFERENCE TO RELATED APPLICATION

The present application claims priority to Korean Patent Application No. 10-2020-0010991, filed Jan. 30, 2020, the entire contents of which is incorporated herein for all purposes by this reference.

### BACKGROUND OF THE INVENTION

### Field of the Invention

The present disclosure relates to a laminated anodic oxide film structure in which a plurality of anodic oxide films are stacked.

### Description of the Related Art

An anodic oxide film material may have less thermal deformation under a high-temperature atmosphere. Therefore, the anodic oxide film can be advantageously used in the semiconductor or display field requiring a high-temperature process atmosphere.

The anodic oxide film may be manufactured in the form of a thin plate and may constitute various components used in the semiconductor or display field. The thinning of the anodic oxide film may be to improve performance efficiency in a specific field.

However, the thin anodic oxide film has a disadvantage in that its strength is low due to its thickness. Therefore, it may be difficult to use the anodic oxide film as a single sheet. For example, when the anodic oxide film is provided as a single sheet on a specific component, this may cause a problem of reducing durability of the entire component due to low strength.

In specific fields using an anodic oxide film, there is a need for a structure in which a plurality of layers are stacked to compensate for low strength of a thin anodic oxide film.

The foregoing is intended merely to aid in the understanding of the background of the present disclosure, and is not intended to mean that the present disclosure falls within the purview of the related art that is already known to those skilled in the art.

### DOCUMENTS OF RELATED ART

(Patent document 1) Korean Patent No. 10-0664900

### SUMMARY OF THE INVENTION

Accordingly, the present disclosure has been made keeping in mind the above problems occurring in the related art, and an objective of the present disclosure is to provide a laminated anodic oxide film structure having improved strength by stacking anodic oxide films.

In order to achieve the above objective, according to one aspect of the present disclosure, there is provided a laminated anodic oxide film structure, including: a plurality of anodic oxide film sheets; a protective layer provided on at least one surface of each of the anodic oxide film sheets; and a bonding layer provided between the anodic oxide film sheets to bond the anodic oxide film sheets to each other, wherein the laminated anodic oxide film structure may have a surface formed by a barrier layer.

Furthermore, the protective layer may be made of a metal oxide, a metal nitride, or a polymer.

Furthermore, wherein each of the anodic oxide film sheets may include a through-hole.

Furthermore, a probe may be provided in the through-hole.

According to the present disclosure, it is possible to secure excellent mechanical strength by the laminated structure. In addition, the present disclosure can prevent warpage deformation by ensuring uniform density of the surface of the laminated structure, and can be used as a configuration in various fields, thereby exhibiting effects of excellent strength and durability in terms of structure.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a view illustrating a laminated anodic oxide film structure according to an embodiment of the present disclosure;

FIG. 2 is a view schematically illustrating an embodiment in which the laminated anodic oxide film structure according to the present disclosure is provided in a specific configuration; and

FIG. 3 is an enlarged view illustrating the laminated anodic oxide film structure illustrated in FIG. 2.

### DETAILED DESCRIPTION OF THE INVENTION

Contents of the description below merely exemplify the principle of the present disclosure. Therefore, those of ordinary skill in the art may implement the theory of the present disclosure and invent various apparatuses which are included within the concept and the scope of the present disclosure even though it is not clearly explained or illustrated in the description. Furthermore, in principle, all the conditional terms and embodiments listed in this description are intended for the purpose of understanding the concept of the present disclosure clearly, and one should understand that this invention is not limited the exemplary embodiments and the conditions.

The above described objectives, features, and advantages will be more apparent through the following detailed description related to the accompanying drawings, and thus those of ordinary skill in the art may easily implement the technical spirit of the present disclosure.

The embodiments of the present disclosure will be described with reference to cross-sectional views and/or perspective views which schematically illustrate ideal embodiments of the present disclosure. For explicit and convenient description of the technical content, sizes or thicknesses of films and regions and diameters of holes in the figures may be exaggerated. Therefore, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing.

Hereinafter, an exemplary embodiment of the present disclosure will be described in detail with reference to the accompanying drawings.

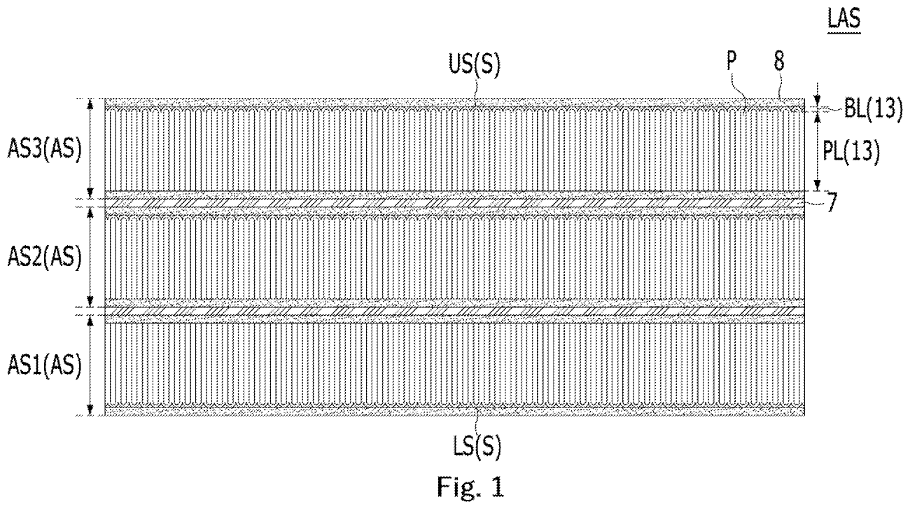

FIG. 1 is a view illustrating a laminated anodic oxide film structure LAS according to the present disclosure.

As illustrated in FIG. 1, the laminated anodic oxide film structure LAS may include a plurality of anodic oxide film sheets AS, a protective layer 8 provided on at least one surface of each of the anodic oxide film sheets AS, and a bonding layer 7 provided between the anodic oxide film sheets AS to bond the anodic oxide film sheets AS to each other.

Each of the anodic oxide film sheets AS may be manufactured by the following process.

First, a process of providing and anodizing an aluminum base material may be performed. By this process, an anodic oxide film 13 composed of anodized aluminum (Al₂O₃) is formed on the surface of the base material. The anodic oxide film 13 is divided into a barrier layer BL in which no pores P are formed and a porous layer in which pores P are formed. The barrier layer BL is positioned on the base material, and the porous layer PL is positioned on the barrier layer BL. In the state in which the anodic oxide film 13 having the barrier layer BL and the porous layer PL is formed on the base material, a process of removing the base material may be performed. By this process, only the anodic oxide film 13 composed of anodized aluminum (Al₂O₃) remains.

The anodic oxide film sheet AS may include the porous layer PL having the pores P and the barrier layer BL formed under the porous layer PL to close one ends of the pores P. Therefore, the anodic oxide film sheet AS may have a structure in which upper and lower surfaces thereof are asymmetric.

The porous layer PL and the barrier layer BL may have a difference in density due to the presence or absence of the pores P. Specifically, the barrier layer BL is a region where no pores P exist and thus may have a relatively higher density than the porous layer PL.

In the present disclosure, the protective layer 8 may be provided on at least one surface of each of the anodic oxide film sheets AS. The protective layer 8 may be made of a metal oxide, a metal nitride, or a polymer.

The metal oxide may be at least one selected from among the group consisting of yttrium oxide (YOx), aluminum oxide (AlOx), magnesium oxide (MgOx), nickel oxide (NiOx), zinc oxide (ZnOx), tin oxide (SnOx), titanium oxide (TiOx), and tantalum oxide (TaOx), zirconium oxide (ZrOx), chromium oxide (CrOx), hafnium oxide (HfOx), and berylnium oxide (BeOx).

The metal nitride may be at least one selected from among the group consisting of titanium nitride (TiNx), zirconium nitride (ZrNx), hafnium nitride (HfNx), niobium nitride (NbNx), tantalum nitride (TaNx), vanadium nitride (VNx), chromium nitride (CrNx), molybdenum nitride (MoNx), tungsten nitride (WNx), aluminum nitride (AlNx), gallium nitride (GaNx), indium nitride (InNx), silicon nitride (SiNx), and germanium nitride (GeNx).

The metal oxide and metal nitride may be formed by deposition using any one selected from among sputter deposition, physical vapor deposition (PVD), chemical vapor deposition (CVD), and atomic layer deposition (ALD).

Meanwhile, the protective layer 8 may be provided in the form of a film. In this case, the protective layer 8 may be attached to at least one surface of the anodic oxide film sheet AS.

The protective layer 8, when provided with the above configuration, may have high rigidity and strength characteristics. Thus, rigidity of the anodic oxide film sheet AS may be improved, resulting in improving durability of the entire laminated anodic oxide film structure LAS having a structure in which the plurality of anodic oxide film sheets AS are stacked.

The protective layer 8 may be provided only on one surface of the anodic oxide film sheet AS, or may be provided on each of opposite surfaces thereof including upper and lower surfaces. In the present disclosure, as an example, the protective layer 8 may be provided on each of the opposite surfaces of the anodic oxide film sheet AS.

When the protective layer 8 is provided only on one surface of the anodic oxide film sheet AS, the protective layer 8 is preferably provided on one surface of the porous layer PL. Since the porous layer PL has a relatively low density, strength of one surface thereof may be low. Therefore, by the protective layer 8 provided on one surface of the porous layer PL, the upper and lower surfaces of the anodic oxide film sheet AS may have uniform density and the overall strength of the anodic oxide film sheet AS may be improved.

The protective layer 8 may prevent a problem wherein particles are introduced into the anodic oxide film sheet AS and a problem wherein particles are introduced into the laminated anodic oxide film structure LAS. The protective layer 8 may be provided on at least one surface of each of the anodic oxide film sheets AS so that the protective layer 8 may be provided on a surface S of the laminated anodic oxide film structure LAS. Therefore, the protective layer 8 may prevent a problem wherein particles are introduced not only into each of the anodic oxide film sheets AS, but also into the laminated anodic oxide film structure LAS.

Meanwhile, the protective layer 8 may prevent a scattering problem of particles occurring inside the anodic oxide film sheet AS.

Specifically, the present disclosure may implement a laminated structure in which the plurality of anodic oxide film sheets AS are joined together by thermal compression. In this case, each of the anodic oxide film sheet AS may include the porous layer PL having a relatively low density. The anodic oxide film sheet AS may have the lowest density in openings of the pores P of the porous layer PL.

In the laminated anodic oxide film structure LAS, particles may be generated due to a pressing force in a region where the density of each of the anodic oxide film sheets AS of is lowest during thermal compression. Particles may flow into or scatter into the anodic oxide film sheet AS of an adjacent layer. These particles may cause a problem of performance degradation inside the laminated anodic oxide film structure LAS.

In the present disclosure, the protective layer 8 may be provided on at least one surface of each of the anodic oxide film sheets AS to prevent such particle inflow and scattering problems. The protective layer 8 may be provided on each of the upper and lower surfaces of the anodic oxide film sheet AS, or provided on one surface of the porous layer PL, thereby preventing inflow and scattering of particles.

The anodic oxide film sheet AS may have a different configuration depending on a position provided in the laminated anodic oxide film structure LAS.

As illustrated in FIG. 1, when provided on a layer forming an upper surface US or a lower surface LS of the laminated anodic oxide film structure LAS, the anodic oxide film sheet AS may have a configured including the porous layer PL and the barrier layer BL. In this case, the anodic oxide film sheet AS may be provided such that the barrier layer BL forms the surface S of the laminated anodic oxide film structure LAS.

As an example, the laminated anodic oxide film structure LAS according to the present disclosure may include a first anodic oxide film sheet AS1, a second anodic oxide film sheet AS2, and a third anodic oxide film sheet AS3. In this case, as illustrated in FIG. 1, the laminated anodic oxide film structure LAS may have a structure in which the first anodic oxide film sheet AS1, the second anodic oxide film sheet AS2, and the third anodic oxide film sheet AS3 are stacked sequentially from bottom to top in the drawing.

As illustrated in FIG. 1, the surface S of the laminated anodic oxide film structure LAS may be formed by the first anodic oxide film sheet AS1 and the third anodic oxide film sheet AS3. In this case, each of the first and third anodic oxide film sheets AS1 and AS3 may include the porous layer PL and the barrier layer BL.

The first and third anodic oxide film sheets AS1 and AS3 may be configured so that the surface S of the layer where each of the first and third anodic oxide film sheets AS1 and AS3 is positioned is formed by the barrier layer BL.

Specifically, the first anodic oxide film sheet AS1 may have a structure in which the barrier layer BL is positioned on the porous layer PL. Thus, in the first anodic oxide film sheet AS1, the barrier layer BL may form the upper surface US of the laminated anodic oxide film structure LAS.

Meanwhile, the third anodic oxide film sheet AS3 may have a structure in which the barrier layer BL is positioned under the porous layer PL. Thus, in the third anodic oxide film sheet AS3, the barrier layer BL may form the lower surface LS of the laminated anodic oxide film structure LAS.

With such a structure, the laminated anodic oxide film structure LAS may have the barrier layer BL on the surface S. Thus, in the laminated anodic oxide film structure LAS, the upper and lower surfaces US and LS may have uniform density, so that warpage deformation may not occur.

In addition, the protective layer 8 may be provided on at least one surface of each of the anodic oxide film sheets AS. Thus, in the laminated anodic oxide film structure LAS, the protective layer 8 may be provided on the surface S formed by the barrier layer BL. As such, the laminated anodic oxide film structure LAS according to the present disclosure may have a high degree of high strength and durability due to the structure in which the plurality of anodic oxide film sheets AS are stacked and the respective protective layers 8.

When not provided at a position forming the surface S of the laminated anodic oxide film structure LAS, the anodic oxide film sheet AS may be a configuration including the porous layer PL and the barrier layer BL, or may include only the porous layer PL.

As illustrated in FIG. 1, the second anodic oxide film sheet AS2 may be provided between the first and third anodic oxide film sheets AS1 and AS3 forming the surface S of the laminated anodic oxide film structure LAS.

The second anodic oxide film sheet AS2 may include the porous layer PL and the barrier layer BL, or may include only the porous layer PL. In the present disclosure, as an example, the second anodic oxide film sheet AS2 may include the porous layer PL and the barrier layer BL provided on the porous layer PL.

As such, in the laminated anodic oxide film structure LAS, the structure of a configuration (e.g., the second anodic oxide film sheet AS2) provided between anodic oxide film sheets (e.g., the first and third anodic oxide film sheets AS1 and AS3) forming the surface S of the laminated anodic oxide film structure LAS may be embodied in various ways.

As illustrated in FIG. 1, the second anodic oxide film sheet AS2 may be provided between the first and third anodic oxide film sheets AS1 and AS3 forming the surface S of the laminated anodic oxide film structure LAS. In this case, even when the second anodic oxide film sheet AS2 has an asymmetric upper and lower surfaces or is composed of only the porous layer PL, rigidity may be secured by the protective layer 8.

In addition, in the second anodic oxide film sheet AS2, a problem of particle generation and particle scattering occurring between the first and third anodic oxide film sheets AS1 and AS3 may be prevented by the protective layer 8.

The laminated anodic oxide film sheet AS may include the bonding layer 7 between each of the anodic oxide film sheets AS. The respective bonding layers 7 may bond the anodic oxide film sheets AS to each other between the anodic oxide film sheets AS.

In the present disclosure, the protective layer 8 may be provided on each of the upper and lower surfaces of each of the anodic oxide film sheets AS. Therefore, in the laminated anodic oxide film structure LAS, the bonding layer 7 may be provided between opposed protective layers 8 of adjacent anodic oxide film sheets AS.

The bonding layer 7 may be provided by a photolithography process. Therefore, the bonding layer 7 may be made of a photosensitive material having photosensitive properties. As an example, the bonding layer 7 may be a dry film photoresist (DFR). In addition, the bonding layer 7 may be configured to have bonding properties for the purpose of performing a bonding function of bonding the anodic oxide film sheets AS to each other. Therefore, the bonding layer 7 may simultaneously have both the photosensitive properties and bonding properties.

Meanwhile, the bonding layer 4 may be a thermosetting resin. Examples of the thermosetting resin may include polyimide resin, polyquinoline resin, polyamideimide resin, epoxy resin, polyphenylene ether resin, fluororesin, and the like.

The laminated anodic oxide film structure LAS according to the present disclosure may be used in the semiconductor or display field. In this case, the laminated anodic oxide film structure LAS may be provided with an additional configuration depending on its function.

As an example, the laminated anodic oxide film structure LAS may have a through-hole H formed in each of the anodic oxide film sheets AS. In this case, in the laminated anodic oxide film structure LAS, the respective through-holes H of the anodic oxide film sheets AS may be formed at positions corresponding to each other. Thus, the laminated anodic oxide film structure LAS may have the through-holes H passing through the laminated anodic oxide film structure LAS from top to bottom.

The laminated anodic oxide film structure LAS having such a structure may perform different functions depending on a specific field in which the laminated anodic oxide film structure LAS is used. As an example, the laminated anodic oxide film structure LAS may perform a function of spraying a fluid through the through-holes H.

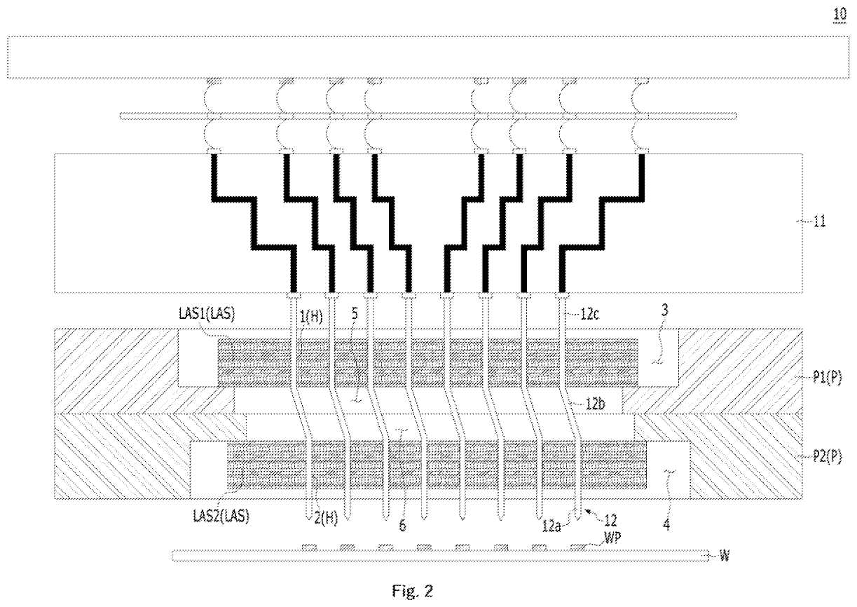

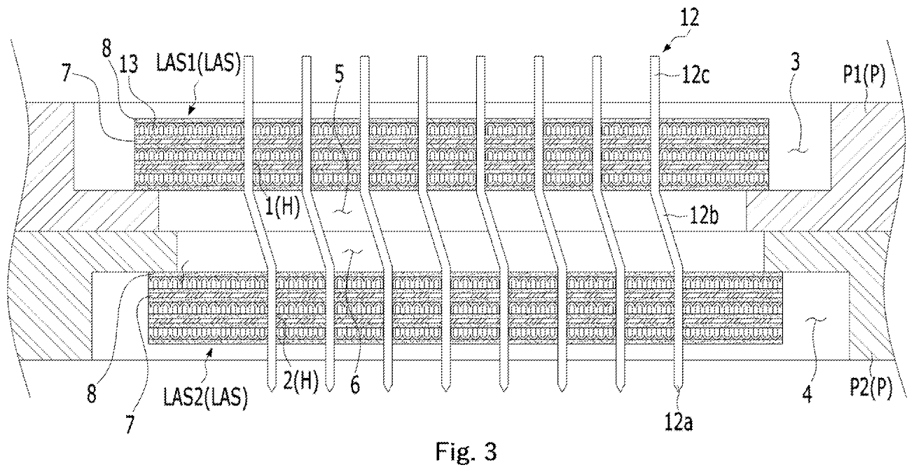

Meanwhile, the laminated anodic oxide film structure LAS may have a separate configuration in the through-holes H to perform a specific function. Specifically, the laminated anodic oxide film structure LAS may include a probe 12 provided in each of the through-holes H. This will be described in detail with reference to FIGS. 2 and 3.

FIG. 2 is a view schematically illustrating a probe card 10 having a laminated anodic oxide film structure LAS according to the present disclosure.

Depending on the structure of installing a probe 12 on a wiring substrate 11 and the structure of the probe 12, the probe card 10 may be divided into a vertical type probe card, a cantilever type probe card, a MEMS probe card.

As illustrated in FIG. 2, the laminated anodic oxide film structure LAS according to the present disclosure may be provided in a vertical type probe card 10 as an example.

The probe card 10 may perform a function of determining whether there is a defect by applying an electric signal to chips constituting a semiconductor wafer W.

Specifically, the probe card 10 may perform an electrical characteristic test by bring the probe 12 into contact with each electrode pad WP of the wafer W. In this case, the probe card 10 may include a guide plate supporting the probe 12 to accurately determining a contact position of the probe 12. The laminated anodic oxide film structure LAS according to the present disclosure may be provided in the probe card 10 to function as a guide plate.

As illustrated in FIG. 2, the laminated anodic oxide film structure LAS may be provided under the wiring substrate 11, with through-holes H each having the probe 12 provided and supported therein.

The laminated anodic oxide film may be provided in the probe card 10 by including an upper laminated anodic oxide film structure LAS1 and a lower laminated anodic oxide film structure LAS2.

In this case, the laminated anodic oxide film structure LAS may be supported by a plate P including first and second plates P1 and P2.

The first and second plates P1 and P2 may have a structure corresponding to each other, and may be coupled to each other in an inverted shape. Specifically, the second plate P2 may be coupled to the bottom of the first plate P1 in a shape inverted from the first plate P1. The plate P may include the laminated anodic oxide film structure LAS therein.

As illustrated in FIG. 3, the first plate P1 may include an upper mounting region 3 for providing the upper laminated anodic oxide film structure LAS1. The second plate P2 may include a lower mounting region 4 for providing the lower laminated anodic oxide film structure LAS2. The first and second plates P1 and P2 may be coupled to each other in inverted shapes. Therefore, the upper mounting region 3 and the lower mounting region 4 may be provided in the same shape at inverted positions

The laminated anodic oxide film structure LAS may have an area smaller than that of the plate P. Thus, except for a surface of the plate P where the laminated anodic oxide film structure LAS is provided, a remaining surface thereof may be exposed.

The laminated anodic oxide film structure LAS according to the present disclosure may be manufactured in a size and structure suitable for a configuration in which the laminated anodic oxide film structure LAS is provided. Thus, when provided in the probe card 10, the present disclosure may exhibit an effect of facilitating handling of the probe card 10.

The laminated anodic oxide film structure LAS may be provided in a configuration including the probe 12. Therefore, the laminated anodic oxide film structure LAS may a configuration forming a substantial probing region. The laminated anodic oxide film structure LAS according to the present disclosure may be provided in the probe card 10 with an area smaller than that of the plate P. Thus, the probe card 10 may be advantageous in minimizing the possibility of direct breakage or damage to the probing region.

The first plate P1 may have a first through-hole 5 formed in a lower portion of the upper mounting region 3, and the second plate P2 may have a second through-hole 6 formed in an upper portion of the lower mounting region 4.

The first and second through-holes 5 and 6 may be provided to allow a plurality of probes 12 inserted through upper and lower through-holes 1 and 2, which will be described later, to be positioned therein. Therefore, the first and second through-holes 5 and 6 may be formed with an inner diameter that can accommodate elastic deformation of the plurality of probes 12.

The plate P may include the laminated anodic oxide film structure LAS in each of the mounting regions 3 and 4.

The upper laminated anodic oxide film structure LAS1 may have the upper through-holes 1, and the lower laminated anodic oxide film structure LAS2 may have the lower through-holes 2. Therefore, the through-holes H of the laminated anodic oxide film structure LAS may include the upper and lower through-holes 1 and 2.

The probes 12 may be separately manufactured and provided. Each of the probes 12 may be first inserted at a first end thereof into each of the upper through-holes 1 and then inserted into each of the lower through-holes 2.

As described above, the laminated anodic oxide film structure LAS may function to guide tips of the probes 12 through the through-holes H.

As illustrated in FIG. 3, each of the probes 12 may be first inserted at the first end thereof into the upper through-hole 1 and then inserted into the lower through-hole 2. Thus, the probe 12 may have a structure in which a second end 12c thereof is positioned in the upper through-hole 1, an intermediate portion 12b thereof is positioned in the first and second through-holes 5 and 6, and the first end 12a inserted first is inserted into the lower through-hole 2 of the laminated anodic oxide film structure LAS2 and protrudes therefrom.

The probes 12 may be manufactured in a vertical shape and may be inserted into the upper and lower through-holes 1 and 2. Then, at least one of the first and second plates P1 and P2 may be moved so that their positions are shifted from each other. Then, the first and second plates P1 and P2 may be coupled to each other in the shifted state. Thus, the probes 12 may have a structure in which the respective intermediate portions 12b are elastically deformed.

In the laminated anodic oxide film structure LAS, with such a structure, a tip of each of the probes 12 may be positioned above a corresponding one of electrode pads WP on the wafer W. Therefore, the laminated anodic oxide film structure LAS may function to guide the tips of the probes 12.

The laminated anodic oxide film structure LAS may be made of anodic oxide films 13 so that it may be easy to form through-holes H having a fine size and a narrow pitch. Thus, the laminated anodic oxide film structure LAS may be advantageous in providing the probes 12 that need to become finer in size and narrower in pitch.

In addition, the laminated anodic oxide film structure LAS may have excellent strength due to the structure in which the plurality of anodic oxide film sheets AS are stacked. In addition, the laminated anodic oxide film structure LAS may further improve mechanical strength of a component itself by providing the protective layers 8 on the surface S. Thus, the laminated anodic oxide film structure LAS may exhibit excellent mechanical strength and durability.

Therefore, when the laminated anodic oxide film structure LAS has the through-holes H, strength and durability of inner walls of the through-holes H may be excellent. When having the probes 12 provided in the through-holes H, the laminated anodic oxide film structure LAS may have abrasion resistance in terms of sliding friction between the probes 12 and the through-holes H.

In addition, the laminated anodic oxide film structure LAS may have less thermal deformation under a high-temperature atmosphere. Therefore, the laminated anodic oxide film structure LAS may be advantageously used in the semiconductor or display field that requires processing under a high-temperature atmosphere.

As an example, the probe card 10 may perform a burn-in test to ensure reliability of chips. The burn-in test may be conducted under a high-temperature environment of 85° C. or 100° C. Thus, the laminated anodic oxide film structure LAS may be exposed to high temperature.

However, the laminated anodic oxide film structure LAS may have less thermal deformation due to high temperature due to its low coefficient of thermal expansion. Therefore, even when the laminated anodic oxide film structure LAS has the through-holes H, a problem of positional deformation of the through-holes H may be prevented. Thus, in the laminated anodic oxide film structure LAS, a problem wherein positional accuracy of the probes 12 provided in the through-holes H is reduced may be prevented.

Therefore, the laminated anodic oxide film structure LAS according to the present disclosure may be provided in the probe card 10 to enable the probe card 10 to more effectively perform a high-temperature process such as a burn-in test process.

As described above, the laminated anodic oxide film structure LAS according to the present disclosure may have an advantage of excellent strength due to the structure in which the plurality of anodic oxide film sheets AS are stacked and the protective layer 8 is provided on at least one surface of each of the anodic oxide film sheets AS.

In addition, since the present disclosure is made of the anodic oxide films 13, the present disclosure may have less thermal deformation and thus may be advantageously used even under a high-temperature environment.

In addition, in the laminated anodic oxide film structure LAS according to the present disclosure, since the surface S is formed by the barrier layer BL, density of the upper and lower surfaces US and LS may be uniform. With this structure, the present disclosure may prevent the problem of warpage deformation.

In other words, the laminated anodic oxide film structure LAS according to the present disclosure may not only secure excellent mechanical strength due to the laminated structure, but may further improve rigidity through the protective layers 8. In addition, the present disclosure may ensure uniform density of the surface S of the laminated structure. Thus, the present disclosure may be more effective in terms of preventing warpage deformation by improving strength of the surface S.

As a result, the laminated anodic oxide film structure LAS according to the present disclosure may be used as a configuration in various fields and exhibit excellent effects in terms of strength and durability.

As described above, the present disclosure has been described with reference to the exemplary embodiment. However, those skilled in the art will appreciate that various modifications, additions and substitutions are possible, without departing from the scope and spirit of the present disclosure as disclosed in the accompanying claims.

What is claimed is:

1. A laminated anodic oxide film structure, comprising:
a plurality of anodic oxide film sheets;
a protective layer provided on at least one surface of each of the anodic oxide film sheets; and
a bonding layer provided between the anodic oxide film sheets to bond the anodic oxide film sheets to each other.

2. The laminated anodic oxide film structure of claim 1, wherein the laminated anodic oxide film structure has a surface formed by a barrier layer.

3. The laminated anodic oxide film structure of claim 1, wherein the protective layer is made of a metal oxide, a metal nitride, or a polymer.

4. The laminated anodic oxide film structure of claim 1, wherein each of the anodic oxide film sheets comprises a through-hole.

5. The laminated anodic oxide film structure of claim 4, wherein a probe is provided in the through-hole.
